(19) United States
(12) Patent Application Publication
(10) Pub. No.: US 2022/0099756 A1
(43) Pub. Date: Mar. 31, 2022

(54) METHOD FOR PROVIDING SELF-DETECTION OF AN OPEN-CIRCUIT OR CLOSED-CIRCUIT CONDITION IN A DIELECTRIC DEVICE

(71) Applicants: iCare Diagnostics International Co. Ltd., New Taipei City (TW); Century Technology (Shenzhen) Corporation Limited, Shenzhen (CN)

(72) Inventors: HUNG-YUN HUANG, New Taipei (TW); KENG-YUAN CHEN, New Taipei (TW); WEI-YANG HSU, New Taipei City (TW); CHUNG-YAO CHEN, New Taipei (TW); YU-FU WENG, New Taipei (TW)

(21) Appl. No.: 17/474,311

(22) Filed: Sep. 14, 2021

Related U.S. Application Data
(60) Provisional application No. 63/085,368, filed on Sep. 30, 2020.
(60) Provisional application No. 63/085,385, filed on Sep. 30, 2020.
(60) Provisional application No. 63/137,597, filed on Jan. 14, 2021.

(30) Foreign Application Priority Data
Jul. 1, 2021 (CN) 202110746173.8

(51) Int. Cl. G01R 31/52; H03F 3/45

(52) U.S. Cl. CPC G01R 31/52; H03F 3/45475

(57) ABSTRACT

An electrowetting on dielectric (EWOD) device for self-detection of an open-circuit or closed-circuit condition includes a detection chip, a power input module, a switch module, a detection module, and a determination module. The detection chip includes a channel, several driving electrodes, and a detection electrode. Each driving electrode can couple with the detection electrode to form the driving loop. The switch unit selects one of the driving electrodes to be electrically connected to the power input module for receiving a power voltage from the power input module. The detection module receives a detection voltage outputted by the detection electrode and accumulates the detection voltage to obtain an accumulated voltage. The determination module compares the accumulated voltage with a specified voltage for determining whether the driving loop is open-circuit or closed-circuit. A method for a self-detection circuit in EWOD device is also disclosed.

### FIELD

The subject matter herein generally relates to nucleic acid testing, and particular to a method for circuit self-detection of an electrowetting on dielectric device.

### BACKGROUND

A sample droplet of (for example) nucleic acid for an amplification reaction is realized by an electrowetting on dielectric (EWOD) principle. An EWOD device controls the sample droplet to move along a specified path, driven by an electrode, thus a nucleic acid amplification step can be completed. Before using the EWOD device, it is necessary to determine whether a working state of the EWOD circuit is working normal before executing the amplification step.

There is room for improvement in the art.

### BRIEF DESCRIPTION OF THE FIGURES

Implementations of the present disclosure will now be described, by way of example only, with reference to the attached figures.

FIG. 1 is a diagram illustrating an embodiment of a detection chip.

FIG. 2 is a diagram illustrating an embodiment of an electrowetting on dielectric (EWOD) device.

FIG. 3 is a circuit diagram illustrating an embodiment of the EWOD device of FIG. 2.

FIG. 4 is a circuit diagram illustrating an embodiment of the EWOD device of FIG. 2 in a normal state.

FIG. 5 are waveforms illustrating an embodiment of voltages of the EWOD device of FIG. 3.

FIG. 6 is a circuit diagram illustrating an embodiment of the EWOD device of FIG. 3 in an open circuit state.

FIG. 7 are waveforms illustrating an embodiment of voltages of the EWOD device of FIG. 6 in an open circuit state.

FIG. 8 is a circuit diagram illustrating an embodiment of the EWOD device of FIG. 3 in the short circuit state.

FIG. 9 are waveforms illustrating an embodiment of voltages of the EWOD device of FIG. 8 in the short circuit state.

### DETAILED DESCRIPTION

The present disclosure is described with reference to accompanying drawings and the embodiments. It will be understood that the specific embodiments described herein are merely some embodiments, not all the embodiments.

It is understood that, the term “coupled” is defined as connected, whether directly or indirectly through intervening components, and is not necessarily limited to physical connections. The connection can be such that the objects are permanently connected or releasably connected. The terms “perpendicular”, “horizontal”, “left”, “right” are merely used for describing, but not being limited.

Unless otherwise expressly stated, all technical and scientific terminology of the present disclosure are the same as understood by persons skilled in the art. The terminology used in the description of the various described embodiments herein is for the purpose of describing particular embodiments only and is not intended to be limiting. The term “comprising” means “including, but not necessarily limited to”; it specifically indicates open-ended inclusion or membership in a so-described combination, group, series, and the like.

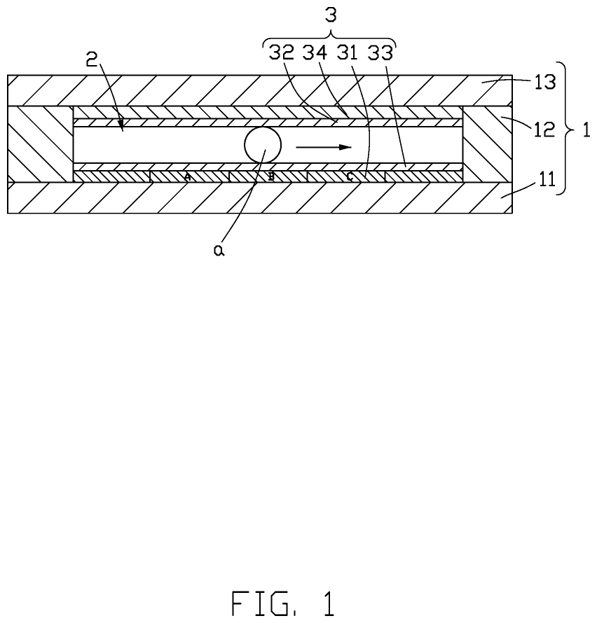

FIG. 1 illustrates one embodiment of a detection chip 10. The detection ship 10 includes a chip casing 1, a channel 2, and a driving loop 3. The channel 2 is disposed in the chip casing 1 and receives a droplet D with a to-be-detected sample of nucleic acid or other sample. The droplet D will undergo a nucleic acid amplification reaction in the channel 2.

The chip casing 1 includes a first cover 11, a spacer layer 12, and a second cover 13. Two opposite surfaces of the spacer layer 12 are respectively adjacent to the first cover 11 and the second cover 13. The first cover 11, the spacer layer 12, and the second cover 13 form the channel 2.

The driving loop 3 drives the droplet D to move along a specified path for executing the nucleic acid amplification reaction. The driving loop 3 includes some driving electrodes 31 disposed on a side surface of the first cover 11 adjacent to the channel 2, a first dielectric layer 33 disposed on a side of the driving electrodes 31 adjacent to the second cover 13, a detection electrode 32 disposed on a side surface of the second cover 13 adjacent to the channel 2, and a second dielectric layer 34 disposed on a side of the detection electrode 32 adjacent to the first cover 11. The driving electrodes 31 and the detection electrode 32 are disposed on opposite sides of the channel 2. By powering on and powering off the driving electrode 31 and the detection electrode 32, the droplet D in the channel 2 is moved along the specified path.

In one embodiment, as shown in FIG. 1, the driving electrodes 31 in the driving loop 3 are arranged in a matrix. A conductive layer disposed on a side surface of the second cover 13 adjacent to the channel 2 serves as the detection electrode 32.

In one embodiment, the driving electrodes 31 are disposed on a side of the first cover 11 adjacent to the channel 2. The driving electrodes 31 can be formed by a metal etching manner or by electroplating.

In detail, the driving loop 3 is a thin film transistor (TFT) driving loop. Based on a conductivity of the droplet D and an electrowetting on dielectric (EWOD) principle, the droplet D moves along the specified path in the channel 2. The TFTs enable a circuit between the driving electrode 31 and one of the detection electrode 32 to be turned on or turned off, thus a voltage between the driving electrode 31 and the corresponding detection electrode 32 can be adjusted. A wetting property between the first dielectric layer 33 and the second dielectric layer 34 can be adjusted for controlling the droplet D to move along the specified path. In one embodiment, there are three electrodes 31, such as electrodes A-C, and the principle of the droplet D moving along the specified path is described as below.

As shown in FIG. 1, the droplet D can move on the electrodes A-C. When the droplet D is disposed on the electrode A, a voltage is applied on the electrode B and the detection electrode 32, and a voltage applied to the electrode A and the detection electrode 32 is turned off. The wetting property between the first dielectric layer 33 and the second dielectric layer 34 is changed, which cause a liquid-solid contact angle between the electrode A and the droplet D to increase, and a liquid-solid contact angle between the electrode B and the droplet D decreases, thus the droplet D moves from the electrode A to the electrode B.

Obviously, a liquid driving principle of the detection chip 10 changes the voltage for adjusting hydrophobic characteristics of the first and second dielectric layers 33/34, and an adsorption capacity of the first and second c 33/34 for adsorbing the droplet D is changed, which makes the droplet D move. Thus, when being assembled and before using, the driving loop 3 of the detection chip 10 needs to be checked for an open circuit state or a short circuit state, thus the nucleic acid amplification reaction can be executed smoothly.

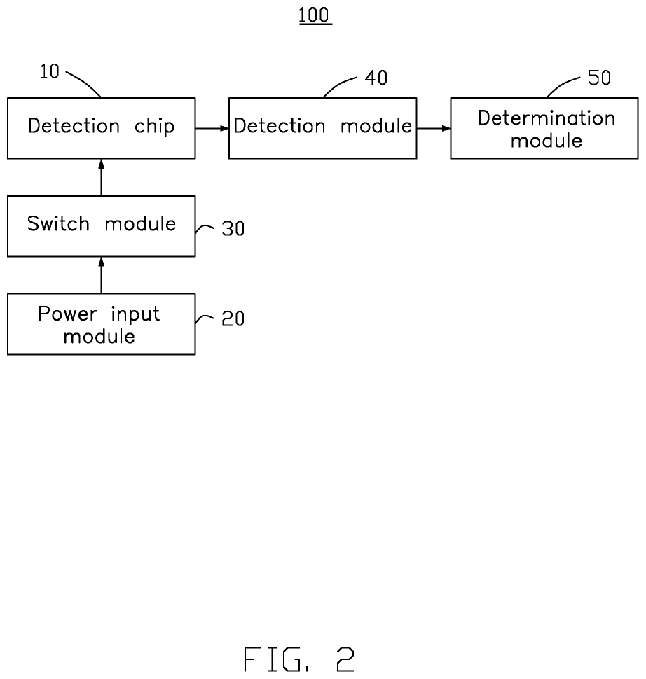

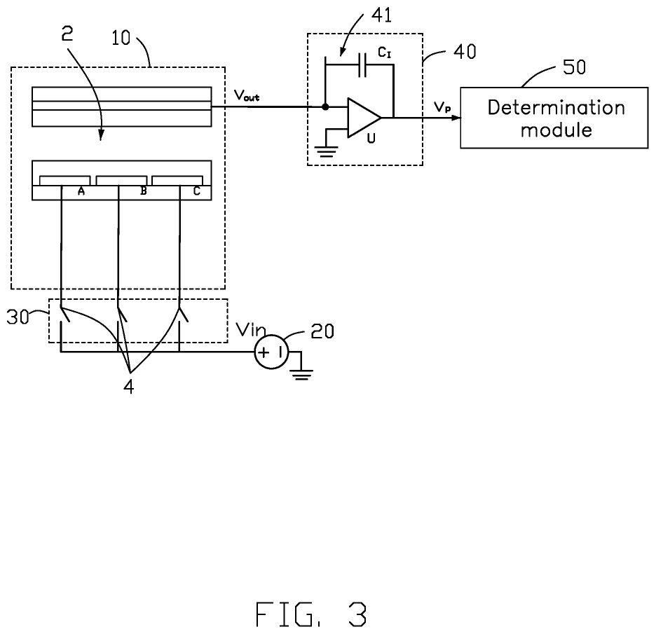

FIGS. 2 and 3 respectively show an embodiment of a diagram and a circuit diagram of a dielectric wetting device 100. The dielectric wetting device 100 includes the detection chip 10, a power input module 20, a switch module 30, a detection module 40, and a determination module 50. The power input module 20 is electrically connected to the detection chip 10 through the switch module 30. In detail, the power input module 20 is electrically connected to the driving electrodes 31 of the detection chip 10 through the switch module 30 and applies a power voltage Vᵢₙ to the driving electrodes 31.

The switch module 30 connects the driving electrodes 31 and the power input module 20. In detail, the switch module 30 includes a plurality of switch units 4. Each switch unit 4 is electrically connected to one of the driving electrodes 31. When the driving electrode 31 couples to the detection electrode 32, the detection electrode 32 receives a detection voltage Vₒᵤₜ (coupled voltage) and outputs the detection voltage Vₒᵤₜ.

The detection module 40 is electrically connected to the detection electrode 32. The detection module 40 receives the detection voltage Vₒᵤₜ outputted by the detection electrode 32, and accumulates the detection voltage Vₒᵤₜ to obtain an accumulation voltage Vₚ. By accumulating the detection voltage Vₒᵤₜ, a sight deviation signal can be accumulated, and when the accumulated voltage Vₚ reaches a specified voltage Vᵣ, the accumulated voltage Vₚ is outputted. Thus, an error or potential error is removed, and veracity of detection is improved.

In one embodiment, the detection module 40 includes a voltage accumulation circuit 41. The voltage accumulation circuit 41 includes an operational amplifier U and a first capacitor C₁. An output terminal of the detection electrode 32 is electrically connected to a positive terminal of the operational amplifier U and a terminal of the first capacitor C₁. Another terminal of the first capacitor C₁ is electrically connected to an output terminal of the operational amplifier U. A positive terminal of the operational amplifier U is grounded. The output terminal of the operational amplifier U serves as an output terminal of the detection module 40 for outputting the accumulated voltage Vₚ of the detection voltage Vₒᵤₜ.

In one embodiment, the voltage accumulation circuit 41 includes an integrator.

The determination module 50 is electrically connected to the detection module 40. The determination module 50 receives the accumulated voltage Vₚ, and compares the received accumulated voltage Vₚ with the specified voltage Vᵣ for determining either a short circuit state or an open circuit state of the detection chip 10. A position of the detection chip 10 in the short circuit state or in the open circuit state can also be confirmed.

In one embodiment, the voltage accumulation circuit 41 can include the voltage accumulation circuit 41, not being limited. The detection module 40 also can include other circuits, such as a filter circuit.

In one embodiment, the first dielectric layer 33 and the second dielectric layer 34 are hydrophobic insulation layers, such as polytetrafluoroethylene coating. Thus, the first dielectric layer 33 and the second dielectric layer 34 present an insulating and hydrophobic function, the droplet D smoothly moves along the specified path, and fragmentation or breakage of the droplet is prevented while the droplet D being moved.

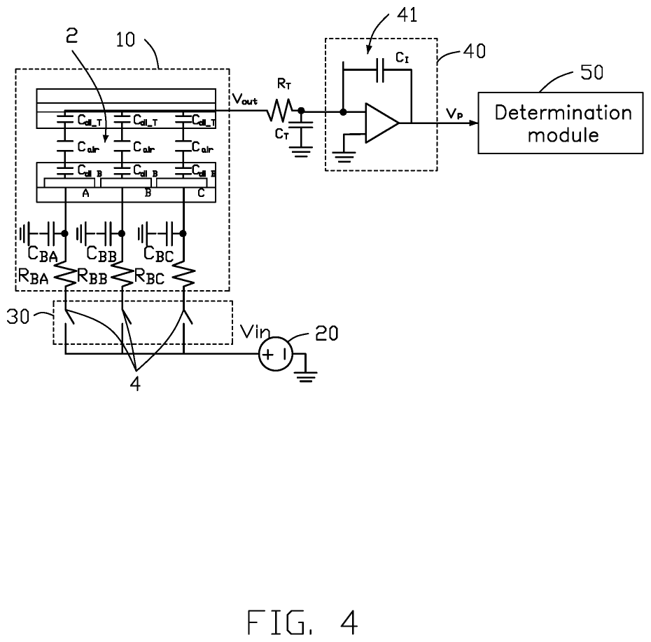

FIG. 4 is a circuit diagram of the EWOD device 100 in one embodiment. Equivalent capacitors are formed in the driving loop 3 between the first dielectric layer 33, the second dielectric layer 34, and the channel 2 of the detection chip 10. The first dielectric layer 33 forms a first dielectric capacitor C_{di-B} in the driving loop 3. The second dielectric layer 34 forms a second dielectric capacitor C_{di-T}. The channel 2 between the first dielectric layer 33 and the second dielectric layer 34 without silicone oil forms an equivalent air capacitor Cₐᵢᵣ. The capacitance of the equivalent air capacitor Cₐᵢᵣ is changed according to a quantity of the silicone oil in the channel 2 between the first dielectric layer 33 and the second dielectric layer 34. In each driving loop 3 formed by each driving electrode 31, the first dielectric capacitor C_{di-B}, the air capacitor Cₐᵢᵣ, and the second dielectric capacitor C_{di-T} are electrically connected in series. A terminal of the first dielectric capacitor C_{di-B} away from the air capacitor Cₐᵢᵣ is electrically connected to the corresponding driving electrode 31, and a terminal of the second dielectric capacitor C_{di-T} away from the air capacitor Cₐᵢᵣ is electrically connected to the detection electrode 32.

In one embodiment, when the switch unit 4 connects with driving electrodes 31 by a wire, a first resistor (R_{BA}, R_{BB}, R_{BC}) (equivalent resistor) and a second capacitor (C_{BA}, C_{BB}, C_{BC}) (equivalent capacitor) are formed based on the wire connecting the switch unit 4 and the driving electrodes 31. In each driving loop 3 formed by each driving electrode 31, the first resistor (R_{BA}, R_{BB}, R_{BC}) and the second capacitor (C_{BA}, C_{BB}, C_{BC}) are electrically connected in series. A terminal of the first resistor (R_{BA}, R_{BB}, R_{BC}) is electrically connected to the switch unit 4, and another terminal of the first resistor (R_{BA}, R_{BB}, R_{BC}) is electrically connected to the corresponding second capacitor (C_{BA}, C_{BB}, C_{BC}) and the corresponding driving electrode 31. Another terminal of the second capacitor (C_{BA}, C_{BB}, C_{BC}) is grounded.

In one embodiment, when the detection electrode 32 is electrically connected to the detection module 40 by a wire, a second resistor R_{T} (equivalent resistor) is formed by the wire connected between the detection electrode 32 and the detection module 40.

In one embodiment, the power voltage Vᵢₙ outputted by the power input module 20 is a continuous square pulsed voltage. The detection voltage Vₒᵤₜ also is a continuous square pulsed voltage.

In one embodiment, the switch module 30, by a controller (not shown), can turn on one of the driving electrodes 31 and the driving electrodes 31 are sequentially detected, a position of the loop between the driving electrode 31 and the detection electrode 32 in the open circuit state or in the short circuit state can be accurately confirmed.

When the detection electrode 32 outputs the detection voltage Vₒᵤₜ to the voltage accumulation circuit 41, the voltage accumulation circuit 41 accumulates the detection voltage Vₒᵤₜ to obtain the accumulation voltage Vₚ. The detection module 40 outputs the accumulation voltage Vₚ to the determination module 50. The determination module 50 compares the accumulation voltage Vₚ with the specified voltage Vᵣ. An open circuit state and a short circuit state in the driving loop 3 can be determined by a difference between the accumulation voltage Vₚ and the specified voltage Vᵣ. The position of the driving loop 3 in the open circuit state or the short circuit state is also confirmed.

The accumulated voltage Vₚ of the driving loop 3 in a normal state firstly needs to be detected for serving as the specified voltage Vᵣ. In the normal state, the accumulated voltage Vₚ of the driving loop 3 is equal to the specified voltage Vᵣ. The circuit detection principle of the EWOD device 100 will be described as below.

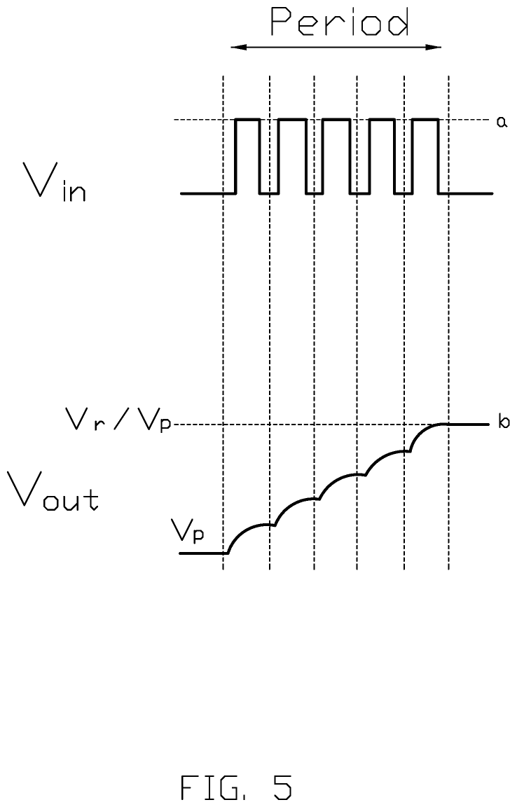

FIG. 4 shows the circuit diagram of the EWOD device 100, and FIG. 5 shows waveforms of voltages of the EWOD device 100.

When the channel 2 of the detection chip 10 is without the silicon oil, the power voltage Vᵢₙ of the power input module 20 (the continuous square pulsed voltage as shown in FIG. 5) is provided to a driving loop 3 with a specified driving electrode 31 through the switch module 30. The detection voltage Vₒᵤₜ is outputted by the detection electrode 32. The detection voltage Vₒᵤₜ is accumulated by the voltage accumulation circuit 41 (an integrator) of the detection module 40 to obtain the accumulated voltage Vₚ (as shown in FIG. 5). The detection module 40 outputs the accumulated voltage Vₚ to the determination module 50 for comparing.

For example, when the switch unit 4 of the switch module 30 is electrically connected to the electrode A, the electrode A and the detection electrode 32 form a driving loop 3. The continuous square pulsed voltage of the power input module 20 is provided to the electrode A through the equivalent resistor R_{BA}, the electrode A couples with the detection electrode 32, and the detection electrode 32 outputs the detection voltage Vₒᵤₜ (coupled voltage) to the voltage accumulation circuit 41 (integrator) through the equivalent resistor between the detection electrode 32 and the detection module 40. The voltage accumulation circuit 41 accumulates the detection voltage Vₒᵤₜ to obtain the accumulated voltage Vₚ, and outputs the accumulated voltage Vₚ to the determination module 50. When receiving the accumulated voltage Vₚ, the determination module 50 computes the difference between the accumulated voltage Vₚ and the specified voltage Vᵣ to determine whether the EWOD device 100 is in a normal state.

As shown in FIG. 5, in one cycle of the continuous square pulsed voltage, a peak voltage of the detection voltage Vₒᵤₜ serves as the accumulated voltage Vₚ of the EWOD device 100 in the normal state. In one embodiment, the waveform of the accumulated voltage Vₚ is overlapped with the waveform of the specified voltage Vᵣ, and the accumulated voltage Vₚ is equal to the specified voltage Vᵣ. Therefore, the EWOD device 100 in this situation is in the normal state.

It is understood that, when the channel 2 of the detection chip 10 is filled with the silicon oil, the circuit detection principle is same. The accumulated voltage Vp when the channel 2 is filled with the silicon oil is different from the accumulated voltage Vp when the channel 2 of the detection chip 10 is without the silicon oil.

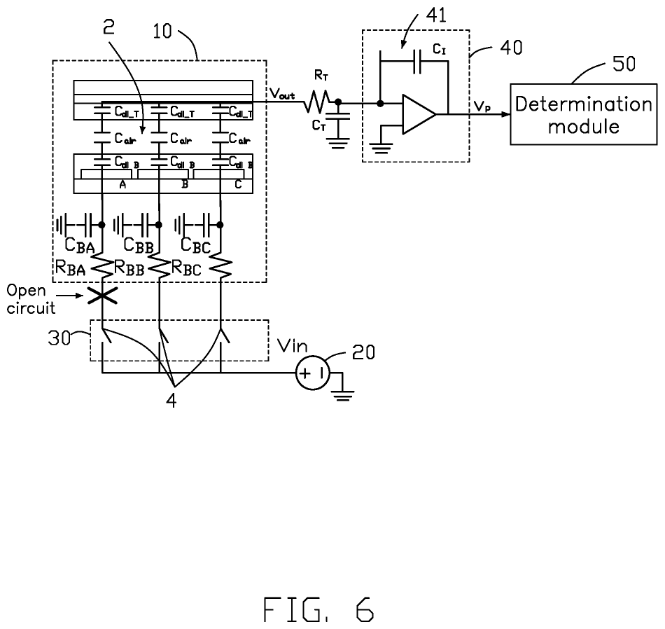

FIG. 6 shows the circuit diagram of the EWOD device 100 in the open circuit state.

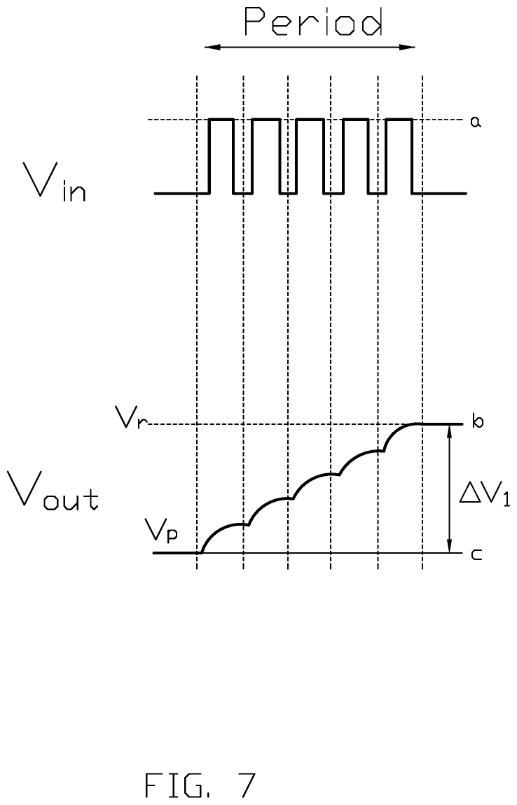

As shown in FIG. 6, the power voltage Vᵢₙ of the power input module 20 (the continuous square pulsed voltage as shown in FIG. 7) is provided to a driving loop 3 with the specified driving electrode 31 through the switch module 30. When the driving loop 3 is in the open circuit state, the power voltage Vᵢₙ of the power module 20 is not provided to the specified electrode 31 through the switch module 30 and the detection electrode 32, and the detection electrode 32 does not output the detection voltage Vₒᵤₜ. Thus, the voltage accumulation circuit 41 (integrator) of the detection module 40 does not receive the detection voltage Vₒᵤₜ, and does not accumulate the detection voltage Vₒᵤₜ to obtain the accumulated voltage Vₚ. Therefore, the determination module 50 easily determines that the driving loop 3 of the specified driving electrode 31 is in the open circuit state.

When the circuit with the electrode A is in the open circuit state, the detection module 40 does not receive the detection voltage Vₒᵤₜ to obtain the accumulated voltage Vₚ. The voltage difference ΔV₁ between the voltage detected by the detection module 40 and the specified voltage Vᵣ is used for determining whether the driving loop 3 is in the open circuit state. As shown in FIG. 7, the waveform of the detection voltage Vₒᵤₜ in the normal state with the peak voltage is equal to the specified voltage Vᵣ. The waveform of the detection voltage Vₒᵤₜ is the straight line below the waveform of the detection voltage Vₒᵤₜ in the normal state. The detection module 40 does not receive the detection voltage Vₒᵤₜ, thus there is no accumulated voltage Vₚ. The straight line in FIG. 7 represents the accumulated voltage Vₚ. The voltage difference ΔV₁ is a difference between the accumulated voltage Vₚ and the specified voltage Vᵣ. The voltage difference ΔV₁ becomes larger. By a shape of the curved line C and the voltage difference ΔV₁, it can be determined that the driving loop 3 of the electrode A is in the open circuit state.

Whether or not other wires connected to other driving electrode 31 or connected to the detection electrode 32 are the open circuit state can be detected by the same detection principle as above.

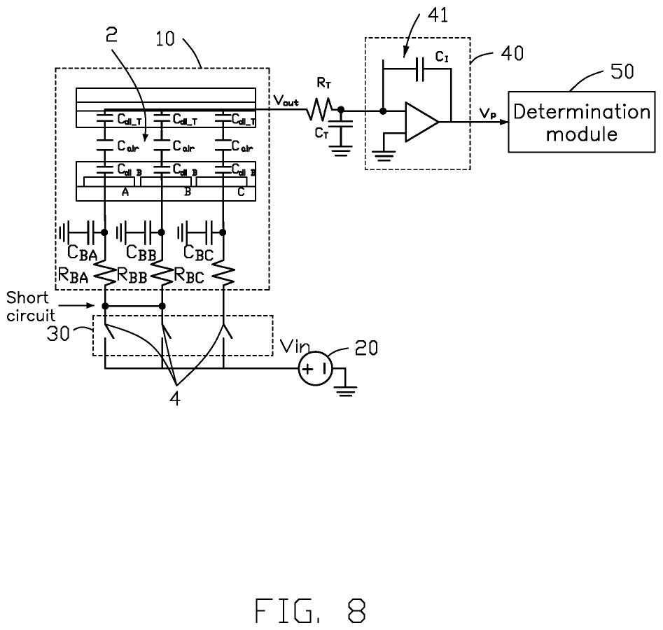

FIG. 8 shows the circuit diagram of the EWOD device 100 in the short circuit state.

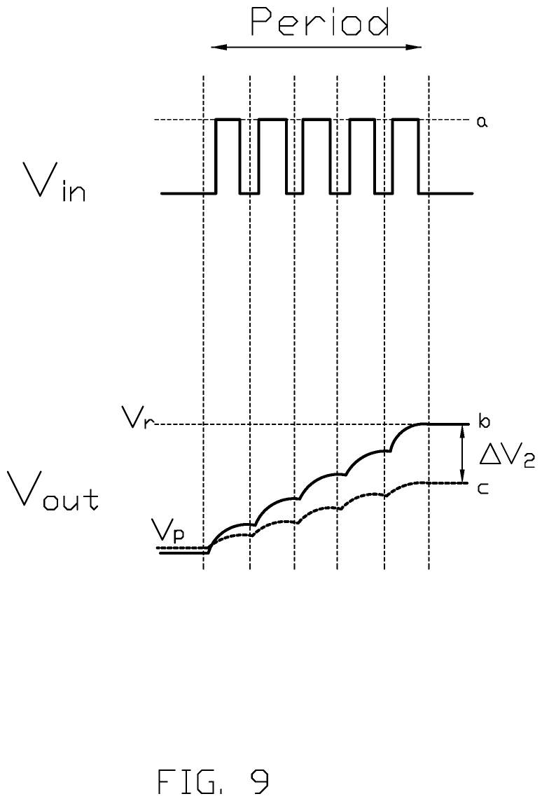

As shown in FIG. 8, the power voltage Vᵢₙ of the power input module 20 (the continuous square pulsed voltage as shown in FIG. 9) is provided to a driving loop 3 with the specified driving electrode 31 through the switch module 30. The detection electrode 32 outputs the detection voltage Vₒᵤₜ, and the voltage accumulation circuit 41 (integrator) of the detection module 40 accumulates the detection voltage Vₒᵤₜ to obtain the accumulated voltage Vₚ. The detection module 40 outputs the accumulated voltage Vₚ to the determination module 50 for comparing. When the driving loop 3 is in the short circuit state, the power voltage Vᵢₙ of the power module 20 is not provided to the circuit through the switch module 30, different wires between the specified driving electrode 31 are electrically connected with each other, the resistance of the first resistors (R_{BA}, R_{BB}, R_{BC}) being driven is increased, and the accumulated voltage Vₚ decreases. The voltage difference ΔV₂ between the accumulated voltage Vₚ and the specified voltage Vᵣ is used for determining whether the driving loop 3 is in the short circuit state. As shown in FIG. 9, the curved line b shows the detection voltage Vₒᵤₜ in the normal state, and the curved line c shows the accumulated voltage Vₚ. When the driving loop 3 is in the short circuit state, a slope of the curved line c of the accumulated voltage Vₚ is less than a slope of the curved line b of the detection voltage Vₒᵤₜ in the normal state. The voltage difference ΔV₂ in the short circuit state is less than the voltage difference ΔV₁ in the open circuit state. Therefore, the driving loop 3 with the specified driving electrode 31 is determined as being short circuited according to the voltage difference ΔV₂ and the accumulated voltage Vₚ.

When the wire connected to the electrode A is in the short circuit state, and is electrically connected to the wire connected to the electrode B, the resistance of the resistor R_{C} of electrode A or B being driven increases, the accumulated voltage Vₚ detected by the voltage accumulation circuit 41 of the detection module 40 decreases, thus the slope of the curved line of the accumulated voltage Vₚ is less than the detection voltage Vₒᵤₜ in the normal state. Therefore, the driving loop 3 with the specified driving electrode 31 is determined as being in the short circuit state according to the voltage difference ΔV₂ and the accumulated voltage Vₚ.

Whether or not other wires connected to other driving electrode 31 or connected to the detection electrode 32 are short circuited can be detected by the same detection principle as above.

When detecting the EWOD device 100, the curved line of the EWOD device 100 being the normal state should be detected firstly as shown in FIG. 5. The curved line of the EWOD device 100 in the normal state serves as a standard line. When the EWOD device 100 is functioning abnormally, the change of the accumulated voltage Vₚ is detected for determining the short circuit state or the open circuit state of the circuit in the EWOD device 100, and the position of the circuit in the EWOD device 100 is also detected. The EWOD device 100 executes a self-detection of the detection chip 10 by the internal circuit of the EWOD device 100, and no external detection device is required. The method for detecting the circuit in the EWOD device 100 is simple, and is easy for operation. The detection result is more accurate. The method has higher efficiency, and a determination as to abnormal functioning is more accurate.

A method for detecting a circuit in the EWOD device 100 includes at least the following steps, which also may be followed in a different order:

In a first step, the switch module 30 is electrically connected to the specified driving electrode 31, thus the power input module 20 provides the power voltage Vᵢₙ to the specified driving electrode 31.

In a second step, the specified driving electrode 31 couples with the detection electrode 32 to generate the detection voltage Vₒᵤₜ (coupled voltage), and the detection electrode 32 outputs the detection voltage Vₒᵤₜ to the detection module 40.

In a third step, the detection module 40 accumulates the detection voltage Vₒᵤₜ to obtain the accumulated voltage Vₚ.

In a fourth step, the determination module 50 compares the accumulated voltage Vₚ with the specified voltage Vᵣ to determine whether the circuit with the specified driving electrode 31 is in the short circuit state or the open circuit state, and the position of the circuit in the short circuit state or the open circuit state is also confirmed.

The determination process is the same as the above detection principle.

The EWOD device 100 can execute a self-detection for detecting the internal circuits. By comparing the accumulated voltage Vp and the specified voltage Vr, the state of the circuit in the EWOD device 100 is confirmed, such as the open circuit state and the short circuit state, and the position of the circuit in the EWOD device 100 is also confirmed. The method for detecting the circuit in the EWOD device 100 is simple, and is easy for operation. The detection result is more accurate. The method has higher efficiency, and a determination as to abnormal functioning is more accurate.

Besides, many variations and modifications can be made to the above-described embodiment(s) of the disclosure without departing substantially from the spirit and principles of the disclosure. All such modifications and variations are intended to be included herein within the scope of this disclosure and protected by the following claims. The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best use the invention and various described embodiments with various modifications as are suited to the particular use contemplated.

What is claimed is:

1. An electrowetting on dielectric (EWOD) device comprising:
a detection chip with a channel and a driving loop disposed on opposite sides of the channel; the driving loop with several driving electrodes and a detection electrode; the driving electrodes disposed on a side of the channel, and the detection electrode disposed on a side of the channel opposite to the driving electrodes; each driving electrode configured to couple with the detection electrode to form the driving loop;
a power input module, electrically connected to the driving electrodes, and configured to output a power voltage to the driving electrodes;
a switch module, disposed between the driving electrodes and the power input module, and configured to select one of the driving electrodes to be electrically connected to the power input module;
a detection module, electrically connected to the detection electrode, and configured to receive a detection voltage outputted by the detection electrode, and accumulate the detection voltage to obtain an accumulated voltage; and
a determination module, electrically connected to the detection module, configured to compare the accumulated voltage with a specified voltage for determining the driving loop in a short circuit state or in an open circuit state.

2. The EWOD device of claim 1, wherein when the driving loop is determined in a short circuit state or in an open circuit state, the determination module further confirms a position of the EWOD device in the short circuit state or in the open circuit state.

3. The EWOD device of claim 1, wherein the detection module comprises a voltage accumulation circuit; the voltage accumulation circuit comprises an operational amplifier and a first capacitor; an output terminal of the detection electrode is electrically connected to a positive terminal of the operational amplifier and a terminal of the first capacitor; another terminal of the first capacitor is electrically connected to an output terminal of the operational amplifier; a positive terminal of the operational amplifier is grounded; the output terminal of the operational amplifier is served as an output terminal of the detection module for outputting the accumulated voltage of the detection voltage.

4. The EWOD device of claim 3, wherein the voltage accumulation circuit comprises an integrator.

5. The EWOD device of claim 1, wherein the driving loop comprises a first dielectric layer disposed on a side of the driving electrode adjacent to the driving electrode and a second dielectric layer disposed on a side of the detection electrode adjacent to the detection electrode.

6. The EWOD device of claim 1, wherein the channel is filled with air and/or silicon oil.

7. The EWOD device of claim 1, wherein the power voltage is a continuous square pulsed voltage.

8. The EWOD device of claim 1, wherein the detection chip comprises a chip casing; the chip casing comprises a first cover, a spacer layer, and a second cover; two opposite surfaces of the spacer layer are respectively adjacent to the first cover and the second cover; the first cover, the spacer layer, and the second cover form the channel; the driving electrodes arranged in a matrix are disposed on a surface of the first cover adjacent to the channel; the detection electrode is disposed on a surface of the second cover adjacent to the channel.

9. A method for detecting a circuit in an electrowetting on dielectric (EWOD) device with a detection chip; the method comprising:
electrically connecting a switch unit with a specified driving electrode for providing a power voltage from a power input module to the specified driving electrode;
forming a driving loop and generating a detection voltage when the specified driving electrode being coupled to a detection electrode;
accumulating the detection voltage by a detection module to obtain the accumulated voltage; and
comparing the accumulated voltage by a determination module with a specified voltage to determining whether a driving loop is in a short circuit state or in an open state.

10. The method of claim 9, wherein the method further comprising:
confirming a position of the driving loop in the short circuit state or in the open circuit state, when the driving loop is in the short circuit state or in the open circuit state.

11. The method of claim 9, wherein the detection module comprises a voltage accumulation circuit; the voltage accumulation circuit comprises an operational amplifier and a first capacitor; an output terminal of the detection electrode is electrically connected to a positive terminal of the operational amplifier and a terminal of the first capacitor; another terminal of the first capacitor is electrically connected to an output terminal of the operational amplifier; a positive terminal of the operational amplifier is grounded; the output terminal of the operational amplifier is served as an output terminal of the detection module for outputting the accumulated voltage of the detection voltage.

12. The method of claim 11, wherein the voltage accumulation circuit comprises an integrator.

13. The method of claim 9, wherein the driving loop comprises a first dielectric layer disposed on a side of the driving electrode adjacent to the driving electrode and a second dielectric layer disposed on a side of the detection electrode adjacent to the detection electrode.

14. The method of claim 9, wherein the channel is filled with air and/or silicon oil.

15. The method of claim 9, wherein the power voltage is a continuous square pulsed voltage.

16. The method of claim 9, wherein the detection chip comprises a chip casing; the chip casing comprises a first cover, a spacer layer, and a second cover; two opposite surfaces of the spacer layer are respectively adjacent to the first cover and the second cover; the first cover, the spacer layer, and the second cover form the channel; the driving electrodes arranged in a matrix are disposed on a surface of the first cover adjacent to the channel; the detection electrode is disposed on a surface of the second cover adjacent to the channel.
